(19) United States
(12) Patent Application Publication
(10) Pub. No.: US 2005/0067667 A1
(43) Pub. Date: Mar. 31, 2005

(54) Fast silicon photodiodes with high back surface reflectance in a wavelength range close to the bandgap

(76) Inventors: Alexander O. Goushcha, Riverside, CA (US); Chris Hicks, Costa Mesa, CA (US); Richard A. Metzler, Mission Viejo, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/672,452

(22) Filed: Sep. 26, 2003

(51) Int. Cl. H01L 31/00

(52) U.S. Cl. 257/431

(57) ABSTRACT

Fast silicon photodiodes with high back surface reflectance in a wavelength range close to the bandgap, and methods of fabrication of such photodiodes. The photodiodes have a patterned oxide or nitride layer on the back surface covered by a metal layer that makes electrical contact with the substrate in a pattern complimentary to the pattern of the oxide or nitride layer. This provided high reflectivity over a large percentage of the back surface, while at the same time providing excellent electrical contact to the back surface.

### BACKGROUND OF THE INVENTION 1. Field of the Invention

The present invention relates to semiconductor photodiodes, in particular to silicon photodiodes with highly reflective back surfaces as well as to methods of fabricating such structures.

2. Prior Art

The performance of silicon photodiodes within the spectral range close to the bandgap (˜1124 nm at 23° C.) depends on the quality of the back surface, as the light penetration depth at these wavelengths is large enough to span the entire thickness of the die. The light reflectance from the back surface of the die should be maximized to improve the responsivity and quantum efficiency of the photodiode.

As shown in FIG. 1, prior art silicon photodiode structures use a sputtered metal layer or plating 1 (usually Au or Al) on the wafer back side over an n+ or p+ layer 2, followed by sintering at ˜400° C. to provide a reliable back side electrical contact. FIG. 1 also schematically shows the photodiode crystal bulk 3 and front side active area diffusion 4. As is well known, such structures are characterized by poor back surface reflectance, which becomes important for the wavelength range of λ≧950 nm, since at these wavelengths the absorption length is comparable to the die thickness. Note that the thickness of a conventional silicon photodiode die is within the range 200 to 500 μm. Such thicknesses are usually required to absorb as much incident near infrared light as possible, thereby maximizing the photodiode responsivity at λ≧950 nm.

To increase the quantum efficiency of silicon photodiodes in the near infrared spectral range, the back surface reflectance should be improved, and corresponding methods using isolation layers are well known from solar cell physics and technology. However, these methods are not readily used in silicon photodiode design. In addition, a dielectric isolation layer 5 with the thickness h between the back side metal and silicon may deteriorate significantly electrical properties of the back side contact, thereby forcing additional measures to improve the photodiodes' parameters such as responsivity, frequency bandwidth, rise time, etc. See FIG. 2.

### BRIEF DESCRIPTION OF THE DRAWINGS

The main ideas of the invention are demonstrated by the accompanying drawings.

FIG. 1 is a simplified schematic cross section of a typical, conventional structure for a front illuminated photodiode with a metal layer sputtered or plated on the die back side.

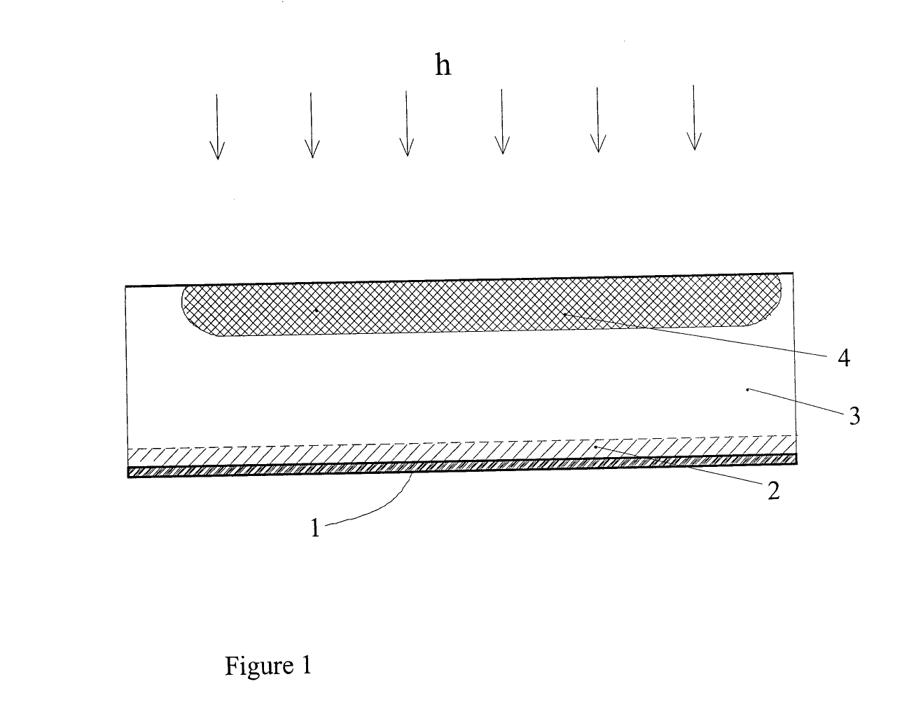

FIG. 2 is a simplified schematic cross section of a front illuminated photodiode with the dielectric isolation layer on the back side.

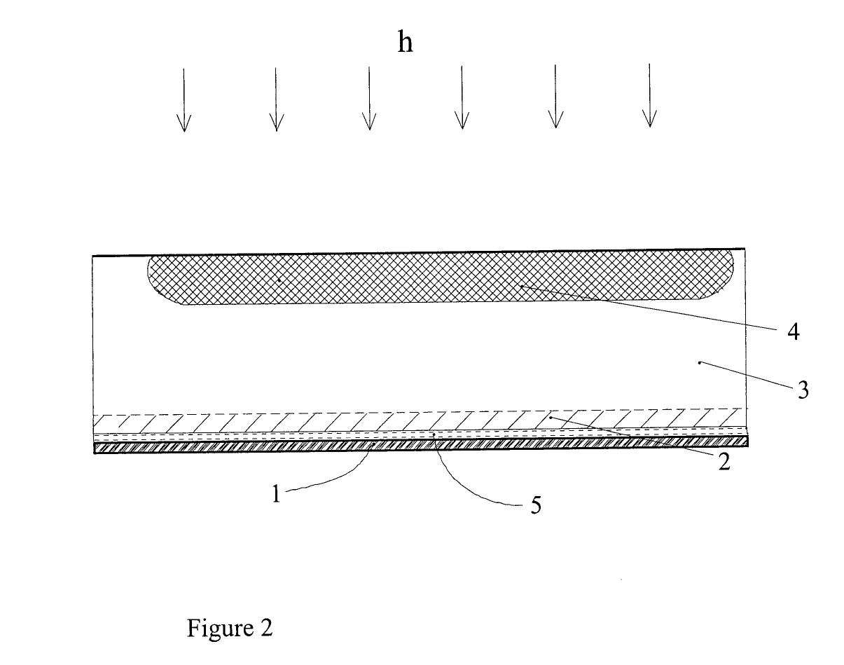

FIG. 3 is a simplified schematic cross section of a photodiode structure having a back side mirror in accordance with the present invention.

FIG. 4 shows schematically one arrangement of electrical contacts on the die back side.

FIG. 5 is a schematic cross section of a completed photodiode in accordance with the present invention.

### DETAILED DESCRIPTION OF THE PREFERRED EMBODIMENTS

As previously discussed, improving the back surface reflectance of photodiodes often causes deterioration of the photodiode performance with respect to such properties as frequency bandwidth and rise time. The present invention uses designs having an additional photomask on the wafer back side. This design corrects the above shortcomings, and provides for superior responsivity and temporal characteristics of silicon photodiodes within the spectral range close to the bandgap.

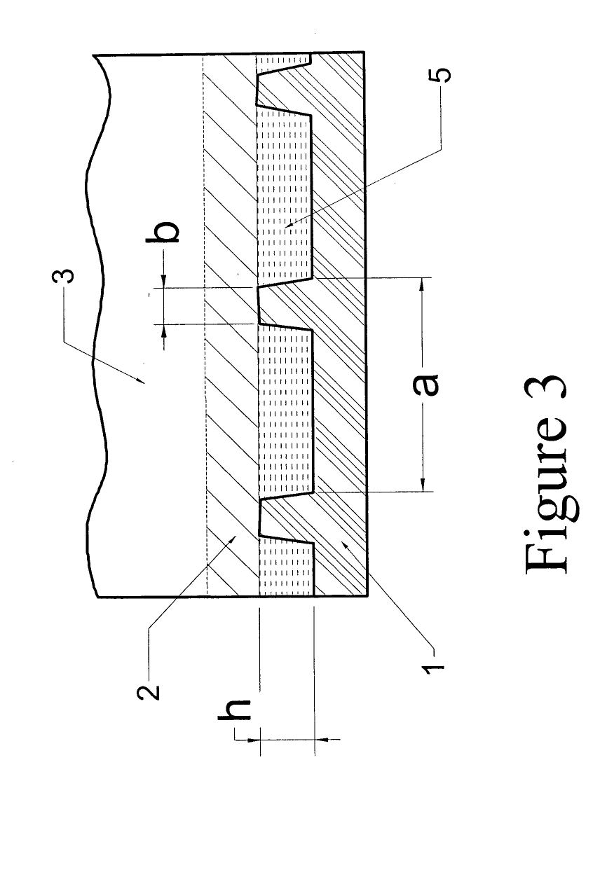

Now referring to FIG. 3, a simplified cross section of a local region illustrating the back side detail of a photodiode in accordance with the present invention may be seen. The structure may be fabricated using either n-type or p-type bulk silicon substrate 3. For brevity, the region 4 of opposite conductivity type on the top surface of the substrate, the anode in the case of p-on-n structure or the cathode in the case of n-on-p structure will be referred to as “the first electrode”, and the cathode in the case of p-on-n structure and the anode in the case of n-on-p structure, will be referred to as “the second electrode”.

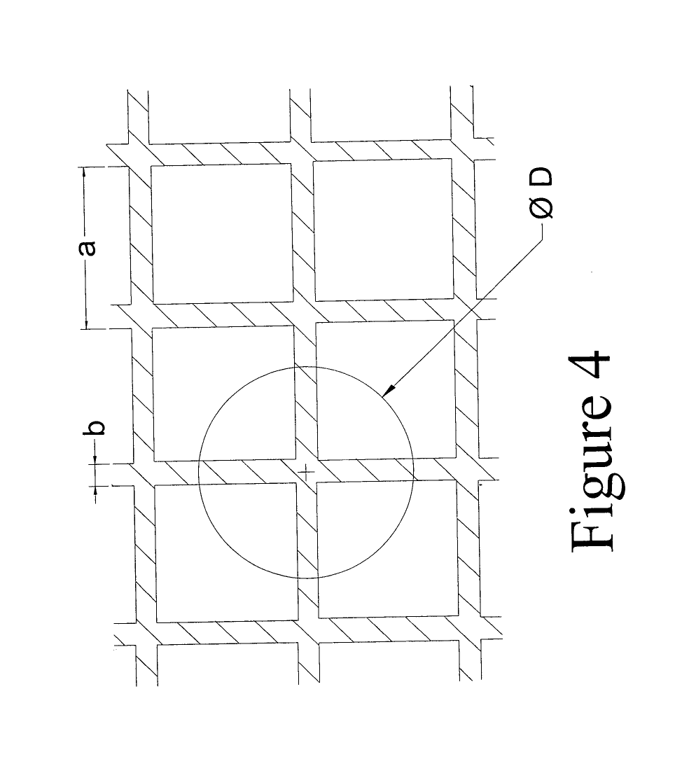

The structure is obtained using an additional photomask/etch process on the back side of the photodiodes, resulting in the so-called “back dielectric mirror” with a periodic contact structure between metal layer 1 and n+ or p+ layer 2 (a layer of the same conductivity type as the substrate 3, though of a higher conductivity than the substrate), like that shown in FIG. 3. The thickness h of the dielectric layer (which, by way of example, may be an oxide or nitride layer) should preferably be approximately 1000 Å. In the exemplary structure of FIG. 3, the extended regions of high reflectance of the back surface are separated from each other by the narrow strips of back side contact metal 1, which serves as the second electrode. The width b of the contact opening strip should be ≧5 μm to provide a secure back side contact. The quality of the back side contact is important to get efficient and rapid collection of the non-equilibrium carriers. At the same time, the width of the contact opening should be kept as narrow as possible because the back side reflection from the contact area is considerably lower than the reflectance from the dielectric mirror. The ratio a/b—see FIG. 3—should be chosen taking into account requirements on the responsivity uniformity across the photodiode active area. For example, if the responsivity should be uniform with an accuracy of 5% when scanning the active area with the 1 mm diameter beam, then the total area S_{cont} of metal contacts enclosed inside the 1 mm diameter circle in any place across the back surface of the die should not exceed the value (see FIG. 4 as an example):

$${S}_{cont} = \frac{π {D}^{2}}{4} \cdot 5 \% = \frac{π {D}^{2}}{4} \cdot 0 , 05 \approx 0.039 sq . mm , \qquad ( 1 )$$

in which D is the beam diameter (D=1 mm in the case of our example). The total area S₀ of the 5-μm width (b=5 μm) metal contacts enclosed within the circle D=1 mm is:
S₀≈2·D·b=2·1·0.005=0.01 sq.mm (2)

From equations 1 and 2, it is clear that S₀<S_{cont}; therefore, 5-μm width contact runs on the die back side satisfy the optimization requirements of securing a good electrical contact and high total reflectance of the back surface of the die.

If for the given structure the requirement S₀≦S_{cont} does not hold, then the values of a and b (see FIGS. 3 and 4) preferably should be changed to keep the ratio a/b within optimal limits.

An exemplary method of fabricating a structure that satisfies the requirements of a high back surface optical reflectance and excellent electrical performance of the photodiode die comprises:

a) A part of the front surface and back surface processing may be standard and is not the object of this invention. It may include, but may not be limited to:

Guard ring/channel stopper deposition, drive, and oxidation—if required (not shown);
Back side contact doping—second electrode—enhancement & oxidation;
Front side first electrode dopant deposition, drive and oxidation;
Front side contact opening;
Front and back side metal deposition and sintering.
   b) The following steps are the objects of this invention:
The back side oxide layer grown during initial steps of wafer processing is not removed;
The additional photo process is applied to open contacts in the oxide layer on the back side. This photo process could either precede the front side contact openings or may immediately follow it. The mask design should be in accord with the considerations given above in the description of the first embodiment of the invention.

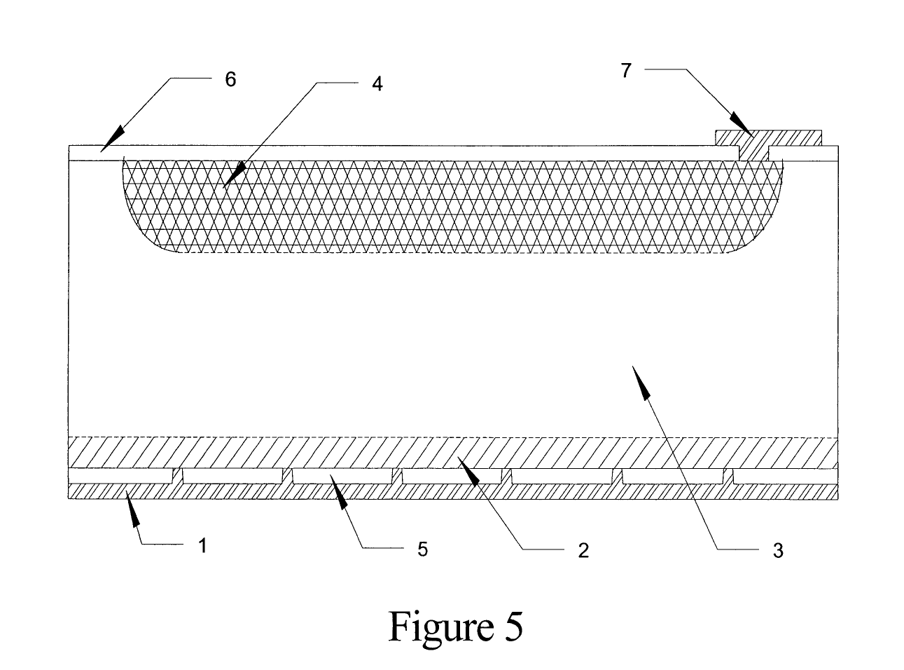

FIG. 5 presents a cross section of an exemplary photodiode in accordance with the present invention. The topside of the photodiodes may be in accordance with the prior art, having a protective oxide layer 6 with a patterned metal layer 7 thereover making contact with the first electrode. The back side incorporates the increased reflectivity over the majority of the back side, yet preserves the desired good electrical contact characteristics, and can be designed to provide a desired uniformity of responsivity over the photodiode area.

Thus, the present invention provides a design for silicon photodiodes and photodiode back side structures that provides high quantum efficiency of the photodiode within the spectral range close to the bandgap, and provides superior temporal characteristics. The present invention also provides related fabrication methods for the photodiodes and photodiode back side structures. The highly reflective back surface structure for silicon photodiodes also greatly improves the photodiode temporal characteristics and, therefore, is useful in construction of fast photodiodes in near infrared spectral range.

1. A photodiode comprising:
a silicon substrate of a first conductivity type having first and second surfaces;
a region of a second conductivity type on the first surface of the substrate;
a region of a first conductivity type on the second surface of the substrate, the region of a first conductivity type on the second surface of the substrate having a higher conductivity than the substrate;
a patterned isolation layer on the region of a first conductivity type on the second surface of the substrate; and,
a metal layer on the patterned isolation layer and contacting the region of a first conductivity type on the second surface of the substrate between regions of the patterned isolation layer.

2. The photodiode of claim 1 wherein pattern of the patterned isolation layer is a repetitive pattern.

3. The photodiode of claim 2 wherein the isolation layer is an oxide layer.

4. The photodiode of claim 2 wherein the isolation layer is a nitride layer.

5. The photodiode of claim 2 wherein the pattern is a repetitive pattern of rectangular regions.

6. The photodiode of claim 1 wherein the substrate is an n-type substrate.

7. The photodiode of claim 1 wherein the substrate is an p-type substrate.

8. The photodiode of claim 1 further comprised of an oxide layer over the region of a second conductivity type and surrounding substrate, and a patterned metal layer over the oxide layer and making electrical contact with the region of a second conductivity type through an opening in the oxide layer.

9. A method of forming a photodiode comprising:
providing a silicon substrate of a first conductivity type having first and second surfaces;
doping the second surface of the substrate to provide a layer of the first conductivity type of higher conductivity than the substrate and providing a layer of oxide thereover;
doping the first surface of the substrate to provide a layer of the second conductivity type and providing a layer of oxide thereover;
masking and etching the oxide layers on the first and second surfaces of the substrate to expose a contact region to the layer of the second conductivity type and to pattern the oxide layer on the second surface to expose a complementary pattern of the layer of the first conductivity type of higher conductivity than the substrate; and,
providing a layer of metal on the second surface of the substrate and a patterned layer of metal on the first surface of the substrate.
